(19) United States
(12) Patent Application Publication
(10) Pub. No.: US 2017/0237911 A1
(43) Pub. Date: Aug. 17, 2017

(54) IMAGE SENSOR HAVING IMPROVED SPECTRAL CHARACTERISTICS

(71) Applicant: SILICONFILE TECHNOLOGIES INC., Seongnam-si (KR)

(72) Inventor: Jun-Ho WON, Seoul (KR)

(21) Appl. No.: 15/029,572

(22) PCT Filed: Nov. 6, 2014
(86) PCT No.: PCT/KR2014/010615

§ 371 Date: Apr. 14, 2016

(51) Int. Cl. H04N 5/33; H04N 9/64; H04N 5/357; H01L 27/146

(52) U.S. Cl. CPC H04N 5/33; H01L 27/14623; H01L 27/14627; H01L 27/14645; H01L 27/14634; H01L 27/1465; H01L 27/14636; H04N 9/646; H04N 5/357

(57) ABSTRACT

The present invention relates to an image sensor sensor having improved spectral characteristics, and improves a color characteristic and sensitivity of an image sensor by implementing an image sensor sensor using a stacked substrate structure having photodiodes formed on each of two substrates, and generating a color signal having improved spectral characteristics based on an electrical signal outputted from each of the photodiodes formed on two substrates.

### TECHNICAL FIELD

The present invention relates to an image, and more specifically, to an image sensor sensor having improved spectral characteristics.

### BACKGROUND ART

Since a semiconductor technique has been developed continuously, a lot of pixels may have been integrated per unit area. However, in case that a lot of pixels are integrated per unit area, the disturbance phenomenon of a signal among neighboring pixels, as a new problem, has risen in prominence. The disturbance phenomenon of the signal among the neighboring pixels is referred to a cross-talk.

A photo signal of the light which is condensed by a micro-lens of an image sensor and passes through an optical filter is converted into an electrical signal by a corresponding photodiode, and the most of photoelectrons are normally captured on a depletion region of the photodiode and constitute an effective current element. But, a portion of the photoelectrons is transitioned to the photodiode of the neighboring pixels and the disturbance phenomenon of the signal is generated. The disturbance of the signal increases as the number of the pixels per unit area increases, i.e., as a width of the photodiodes corresponding to the pixels is narrowed.

In general, the optical filter has different cross-talk characteristics and purity characteristics according to a stacked thickness of the optical filter. In case of a visible ray pixel such as a red color (R), a green color (G) and a blue color (B), a color expression is deteriorated due to the signal generated in a wavelength band of an infrared ray. In case of an infrared pixel, the characteristic of the depth of field (DOF) may be deteriorated due to the signal generated in the wavelength band of the visible ray.

An absorption ratio characteristic of the light in the photodiode of the substrate is different according to the material of the substrate and the wavelength of the light. For example, in case of a silicon (Si) substrate, a silicon (Si) absorption ratio of the infrared wavelength band is relatively lowered, and the light of 60% is absorbed at 10 μm depth of the substrate in the wavelength of 800 nm.

In case of the infrared pixel, it is general to increase the thickness of the substrate, or decrease the thickness of an infrared pass filter disposed on an upper surface in order to raise a reaction of the infrared wavelength band. In a former case, according to the thickness increase (or the depth increase of the photodiode) of the substrate, it may be not easy to transmit a photo-charge due to the restriction of a potential gradient, and in a latter case, the cross-talk phenomenon increases due to the penetration of the light having the visible ray wavelength in the infrared pixel.

In the Korea published patent No. 10-2013-0016518, which is previously filed by the applicant of the present invention and is published on Feb. 18, 2013, a multi-substrate image sensor having a dual detection function with photodiodes on each of two substrates has proposed. The inventor of the present invention has developed an image sensor for improving a spectral characteristic using a stacked substrate structure having the photodiode on each of two substrates.

### DISCLOSURE

### Technical Problem

The present invention is directed to an image sensor sensor for improving spectral characteristics using a stacked substrate structure having photodiodes formed on each of two substrates.

### Technical Solution

In accordance with an embodiment of the present invention, an image sensor having improved spectral characteristics includes a first substrate including a micro-lens suitable for concentrating a light; an optical filter suitable for passing a light of a specific frequency band; and a first photodiode suitable for converting a light signal that passes through the optical filter into an electrical signal, a second substrate including a second photodiode suitable for converting the light signal that passes through the optical filter of the first substrate into the electrical signal; an output driving circuit, which is formed on at least one of the first substrate and the second substrate, suitable for selectively outputting the electrical signals converted by the first photodiode and the second photodiode; and a control unit suitable for generating a color signal having improved spectral characteristics based on the electrical signals, which are converted by each of the first photodiode and the second photodiode and which are outputted from the output driving circuit.

According to an additional aspect of the present invention, the optical filter includes a black and white filter, or a red, green and blue (RGB) color filter.

According to an additional aspect of the present invention, the optical filter further includes an infrared (IR) filter.

According to an additional aspect of the present invention, in case that the optical filter is the RGB color filter, the control unit improves a cross-talk caused by an infrared ray and improves a color characteristic by offsetting an output signal element of the second photodiode from an output signal element of the first photodiode.

According to an additional aspect of the present invention, in case that the optical filter is the black and white filter, the control unit improves a black and white sensitivity characteristic by reinforcing an output signal element of the second photodiode to an output signal element of the first photodiode.

According to an additional aspect of the present invention, in case that the optical filter is the IR filter, the control unit improves a sensitivity characteristic of an infrared ray by reinforcing an output signal element of the second photodiode to an output signal element of the first photodiode.

According to an additional aspect of the present invention, a spectral characteristic is adjusted by adjusting a thickness of at least one of the first substrate and the second substrate.

According to an additional aspect of the present invention, a spectral characteristic is adjusted by adjusting a thickness of at least one of the first photodiode and the second photodiode.

According to an additional aspect of the present invention, the first photodiode and the second photodiode are arrayed in multi-to-multi structure.

According to an additional aspect of the present invention, the first photodiode and the second photodiode are arrayed in multi-to-one structure.

### Advantageous Effects

The present invention may improve a color characteristic and sensitivity of an image sensor by implementing an image sensor using a stacked substrate structure with photodiodes on each of two substrates and by generating a color signal having improved spectral characteristics based on an electrical signal outputted from the photodiodes on each of the two substrates.

### DESCRIPTION OF DRAWINGS

FIG. 1 is an image sensor having improved spectral characteristics in accordance with a first embodiment of the present invention.

FIG. 2 is an image sensor having improved spectral characteristics in accordance with a second embodiment of the present invention.

FIG. 3 is an image sensor having improved spectral characteristics in accordance with a third embodiment of the present invention.

FIG. 4 is a circuit diagram of an image sensor having improved spectral characteristics in accordance with an embodiment of the present invention.

FIG. 5 is an optical filter of an image sensor having improved spectral characteristics in accordance with an embodiment of the present invention.

FIG. 6 is an optical filter of an image sensor having improved spectral characteristics in accordance with another embodiment of the present invention.

FIG. 7 is a photodiode array of an image sensor having improved spectral characteristics in accordance with an embodiment of the present invention.

FIG. 8 is a photodiode array of an image sensor having improved spectral characteristics in accordance with another embodiment of the present invention.

### BEST MODE

Hereinafter, various embodiments will be described below in more detail with reference to the accompanying drawings such that a skilled person in this art understand and implement the present invention easily.

The present invention may, however, be embodied in different forms and should not be construed as limited to the embodiments set forth herein.

In this specification, specific terms have been used. The terms are used to describe the present invention, and are not used to qualify the sense or limit the scope of the present invention.

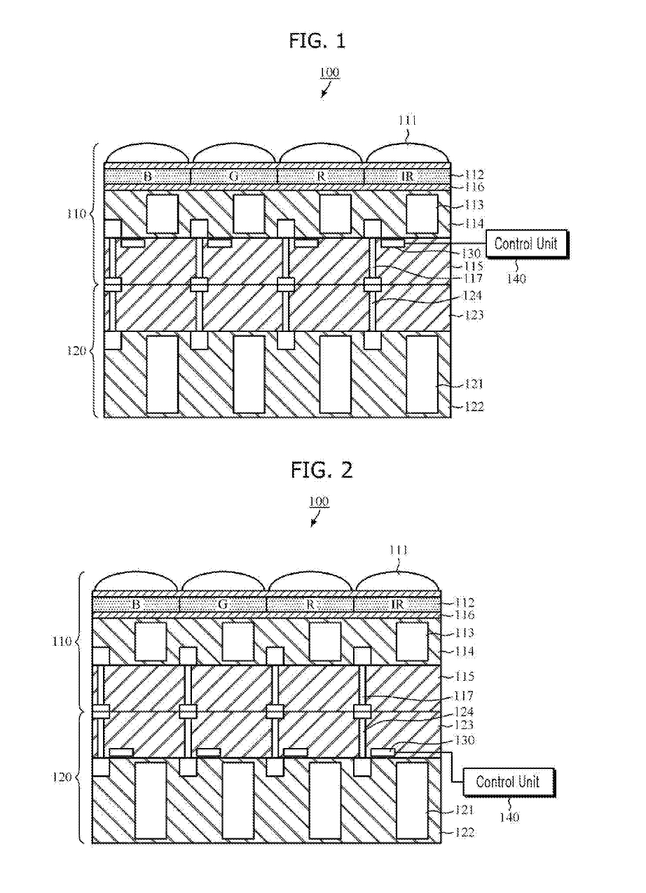

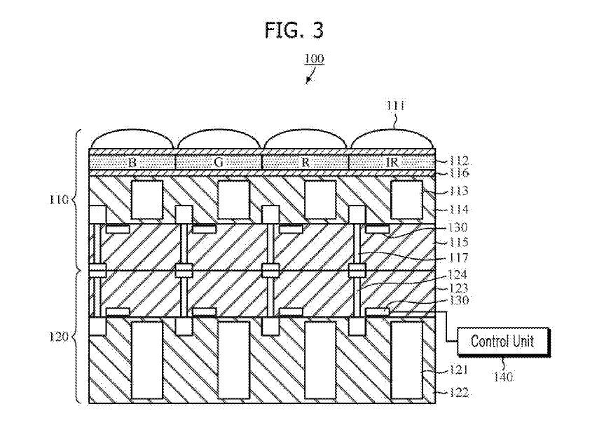

FIG. 1 is an image sensor having improved spectral characteristics in accordance with a first embodiment of the present invention. FIG. 2 is an image sensor having improved spectral characteristics in accordance with a second embodiment of the present invention. FIG. 3 is an image sensor having improved spectral characteristics in accordance with a third embodiment of the present invention.

As shown in FIGS. 1 to 3, an image sensor having improved spectral characteristics in accordance with embodiments of the present invention includes a first substrate 110, a second substrate 120, an output driving circuit 130 and a control circuit 140.

The first substrate 110 includes a micro-lens 111 for concentrating a light, an optical filter 112 for passing an optical signal in a specific frequency band of the light concentrated by the micro-lens, and a first photodiode 113 for converting the optical signal, which passes through the optical filter into an electrical signal. Herein, although not shown in drawings, an optical waveguide or an inner lens may be further included in the first substrate 110 in order to improve a light concentrating ratio of the light, which is concentrated by the micro-lens 111.

The second substrate 120 includes a second photodiode 121 for converting the optical signal, which passes through the optical filter 112 of the first substrate 110, into an electrical signal. The numeral 114 and 112 shown in drawings is a semiconductor layer including a material for adjusting an energy bandgap such as Si, SOI, Ge, SiGe, GaAs, InGaP, InP, InGaAsP, InGaAs, and so on. The numeral 115, 116, 123 are insulation layers, and the numeral 117 and 124 are distribution lines for an electrical coupling.

The output driving circuit 130 is formed on at least one of the first substrate 110 and the second substrate 120, and selectively outputs the electrical signal converted by the first photodiode 113 and the second photodiode 121.

The output driving circuit 130 is formed on the first substrate 110 in FIG. 1, the output driving circuit 130 is formed on the second substrate 120 in FIG. 2, and the output driving circuit 130 is formed on both of the first substrate 110 and the second substrate 120 in FIG. 3.

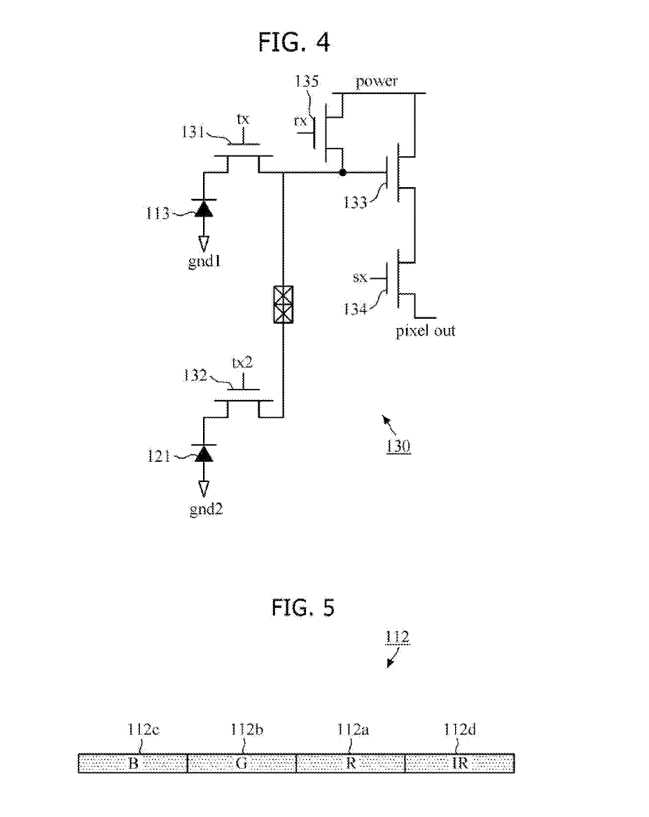

FIG. 4 is a circuit diagram of an image sensor having improved spectral characteristics in accordance with an embodiment of the present invention. As shown in FIG. 4, the output driving circuit 130 includes two transfer transistors 131 and 132, a tracking transistor 133, a selection transistor 134 and a rest transistor 135. All of these elements may be formed on the first substrate 110 or the second substrate 120, and a portion of these elements may be formed on the first substrate 110 and the others may be formed on the second substrate 120.

The two transfer transistors 131 and 132 are coupled to the first photodiode 113 and the second photodiode 121, respectively, and selectively transfers the output of each of the first photodiode 113 and the second photodiode 121.

A source and a drain of the two transfer transistors 131 and 132 are electrically coupled to each other, and are coupled to a gate of the tracking transistor 133. The tracking transistor 133 outputs the electrical signal, which is converted from the photo signal through a source, to a drain according to the electrical signal applied to the gate. The output is switched on or off by the selection transistor 134. The reset transistor 135 resets the output driving circuit 130.

The control unit 140 is a processor for generating a color signal having improved spectral characteristics based on the electrical signal, which is converted by the first photodiode 113 and the second photodiode 121 and is outputted through the output driving circuit 130.

By implementing as described above, the present invention may implement an image sensor having a stacked substrate having photodiodes on the two substrates, and improve a color characteristic and sensitivity of an image sensor by generating a color signal having improved spectral characteristics based on the electrical signal outputted from each of the photodiodes formed on the two substrates.

Meanwhile, according to an additional aspect of the present invention, the optical filter 112 may include a black and white filter, or a red, green, blue (RGB) color filter. Also, the optical filter 112 may further include an infrared (IR) filter.

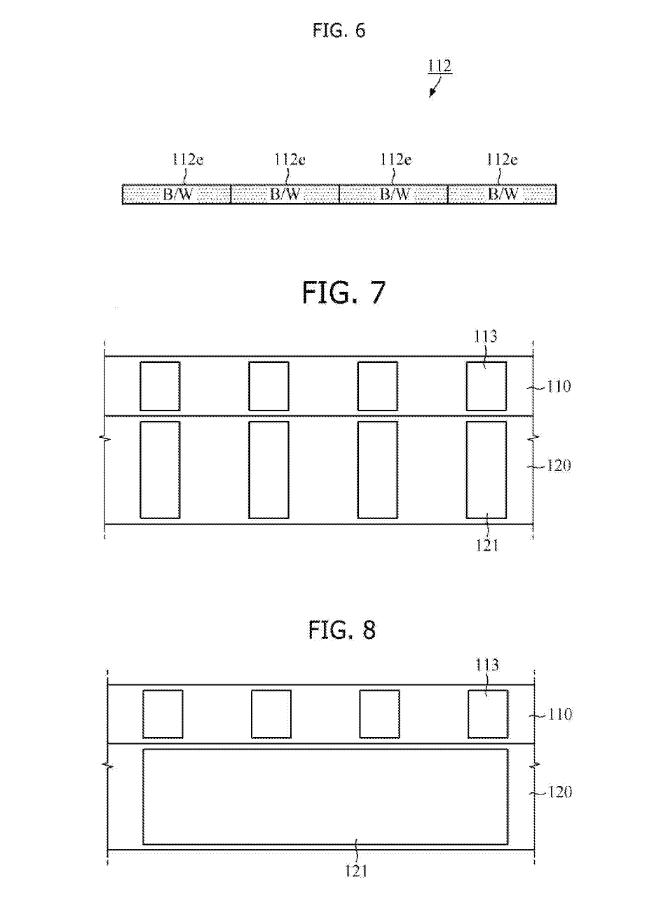

FIG. 5 is an optical filter of an image sensor having improved spectral characteristics in accordance with an embodiment of the present invention, and the RGB color filter 112a, 112b and 112c, and the IR filter 112d are implemented as the optical filter 112. FIG. 6 is an optical filter of an image sensor having improved spectral characteristics in accordance with another embodiment of the present invention, and the black and white filter 112e is implemented as the optical filter 112.

Meanwhile, according to an additional aspect of the present invention, in case that the optical filter 112 is the RGB color filter, the control unit 140 may be implemented to improve a color characteristic by offsetting the output signal element of the second photodiode 121 from the output signal element of the first photodiode 113 and by improving the cross-talk caused by the infrared ray.

For example, to offset the output signal element of the second photodiode 121 from the output signal element of the first photodiode 113 may be implemented by subtracting the output signal of the second photodiode 121 from the output signal of the first photodiode 113.

A light having a wavelength of a visible ray region among the light, which passes through the RGB color filter, is received by the first photodiode 113, but a light having a wavelength of the infrared ray region may be partially received due to the cross-talk of a filter characteristic and the cross-talk generated by the interference between neighboring pixels.

Since the light of the infrared ray region having a long wavelength compared to the light of the visible ray region may be transferred deeply through the medium (the first substrate and the second substrate), the light of the visible ray region is not transferred to the second photodiode 121, and the light of the infrared ray region is received in the second photodiode 121.

Thus, if the output signal of the second photodiode 121 that receives only the light of the infrared region is offset from the output signal of the first photodiode 113 that receives all of the light of visible ray region and the light of the infrared ray region inputted by the cross-talk, only the light of the visible ray region may be acquired, and thus, a color expression, i.e., a color characteristic, of the image sensor may be improved.

Meanwhile, according to an additional aspect of the present invention, in case that the optical filter 112 is the black and white filter, the control unit 140 may be implemented to improve a black and white sensitivity characteristic by reinforcing the output signal element of the second photodiode 121 to the output signal element of the first photodiode 113.

For example, to reinforce the output signal element of the second photodiode 121 to the output signal element of the first photodiode 113 may be implemented by adding the output signal element of the second photodiode 121 to the output signal element of the first photodiode 113.

The black and white light having the wavelength of the visible ray region among the light that passes through the back and white filter is received by the first photodiode 113 and the second photodiode 121, and if the output signal of the first photodiode 113 and the second photodiode 121 that receives the black and white light of the visible ray region are reinforced, the black and white sensitivity of the image sensor may be improved.

Meanwhile, according to an additional aspect of the present invention, in case that the optical filter 112 is the infrared filter, the control unit 140 may be implemented to improve the sensitivity characteristic of the infrared ray by reinforcing the output signal element of the second photodiode 121 to the output signal element of the first photodiode 113.

For example, to reinforce the output signal element of the second photodiode 121 to the output signal element of the first photodiode 113 may be implemented by adding the output signal element of the second photodiode 121 to the output signal element of the first photodiode 113.

The light having the wavelength of the infrared ray region among the light that passes through the IR filter is received by the first photodiode 113, but the light having the wavelength of the visible ray region is partially received due to the cross-talk caused by the filter characteristic and the cross-talk caused by the interference among the neighboring pixels.

Since the light of the infrared ray region having a long wavelength compared to the light of the visible ray region may be transferred to a more deep depth through a medium (the first substrate and the second substrate), the light of the visible ray region is not transferred to the second photodiode 121, and only the light of the infrared ray region is received in the second photodiode 121.

Thus, if the output signal of the second photodiode 121 that receives only the light of the infrared region is reinforced to the output signal of the first photodiode 113 that receives all of the light of visible ray region and the light of the infrared ray region inputted by the cross-talk, the light of the infrared ray region may be further acquired, and thus, the infrared sensitivity of the image sensor may be improved.

Meanwhile, according to an additional aspect of the present invention, a spectral characteristic may be adjusted by the thickness adjustment of at least one of the first substrate 110 and the second substrate. Unlike this, a spectral characteristic may be adjusted by the thickness adjustment of at least one of the first photodiode 113 and the second photodiode 121.

Since the light of the infrared ray region having a long wavelength compared to the light of the visible ray region may be transferred to a more deep depth through a medium (the first substrate and the second substrate), the spectral characteristic may be adjusted by properly adjusting the thickness of the first substrate 110 and the second substrate, or the thickness of the first diode 113 and the second diode 121. For example, in case that the light having a bandwidth under 450 nm wavelength is received, if the first substrate 110 is adjusted to have the thickness of 1-5 μm and the second substrate 120 is adjusted to have the thickness of 3-10 μm, an excellent spectral characteristic may be acquired.

Meanwhile, according to an additional aspect of the present invention, the first photodiode 113 and the second photodiode 121 may be implemented to be arrayed in multi-to-multi structure, and the first photodiode 113 and the second photodiode 121 may be implemented to be arrayed in multi-to-one structure.

FIG. 7 is a photodiode array of an image sensor having improved spectral characteristics in accordance with an embodiment of the present invention. The first photodiode 113 and the second photodiode 121 are arrayed in multi-to-multi structure.

FIG. 8 is a photodiode array of an image sensor having improved spectral characteristics in accordance with another embodiment of the present invention. The first photodiode 113 and the second photodiode 121 are arrayed in multi-to-one structure.

As described above, the present invention improves the color characteristic and the sensitivity of the image sensor and accomplishes the purpose of the present invention by implementing the image sensor with a stacked substrate structure having the photodiodes on each of two substrates, and generating a color signal having improved spectral characteristics based on the electrical signal outputted from each of the photodiodes formed on the two substrates.

Although various embodiments have been described for illustrative purposes, it will be apparent to those skilled in the art that various changes and modifications may be made without departing from the spirit and scope of the invention as defined in the following claims.

1. An image sensor having improved spectral characteristics, comprising:
a first substrate including
a micro-lens suitable for concentrating a light;
an optical filter suitable for passing a light of a specific frequency band; and
a first photodiode suitable for converting a light signal that passes through the optical filter into an electrical signal,
a second substrate including a second photodiode suitable for converting the light signal that passes through the optical filter of the first substrate into the electrical signal;
an output driving circuit, which is formed on at least one of the first substrate and the second substrate, suitable for selectively outputting the electrical signals converted by the first photodiode and the second photodiode; and
a control unit suitable for generating a color signal having improved spectral characteristics based on the electrical signals, which are converted by each of the first photodiode and the second photodiode and which are outputted from the output driving circuit.

2. The image sensor having improved spectral characteristics of claim 1, wherein the optical filter includes a black and white filter, or a red, green and blue (RGB) color filter.

3. The image sensor having improved spectral characteristics of claim 2, wherein the optical filter further includes an infrared (IR) filter.

4. The image sensor having improved spectral characteristics of claim 2, wherein in case that the optical filter is the RGB color filter, the control unit improves a cross-talk caused by an infrared ray and improves a color characteristic by offsetting an output signal element of the second photodiode from an output signal element of the first photodiode.

5. The image sensor having improved spectral characteristics of claim 2, wherein in case that the optical filter is the black and white filter, the control unit improves a black and white sensitivity characteristic by reinforcing an output signal element of the second photodiode to an output signal element of the first photodiode.

6. The image sensor having improved spectral characteristics of claim 3, wherein in case that the optical filter is the IR filter, the control unit improves a sensitivity characteristic of an infrared ray by reinforcing an output signal element of the second photodiode to an output signal element of the first photodiode.

7. The image sensor having improved spectral characteristics of claim 1, wherein a spectral characteristic is adjusted by adjusting a thickness of at least one of the first substrate and the second substrate.

8. The image sensor having improved spectral characteristics of claim 1, wherein a spectral characteristic is adjusted by adjusting a thickness of at least one of the first photodiode and the second photodiode.

9. The image sensor having improved spectral characteristics of claim 1, wherein the first photodiode and the second photodiode are arrayed in multi-to-multi structure.

10. The image sensor having improved spectral characteristics of claim 1, wherein the first photodiode and the second photodiode are arrayed in multi-to-one structure.
